(19) United States
(12) Patent Application Publication
(10) Pub. No.: US 2025/0305149 A1
(43) Pub. Date: Oct. 2, 2025

(54) ETCHING BI-METAL OXIDES WITH ALKALINE EARTH METALS

(71) Applicant: Tokyo Electron Limited, Tokyo (JP)

(72) Inventors: Katie Lutker-Lee, Albany, NY (US); Joshua Baillargeon, Albany, NY (US); Hamed Hajibabaeinajafabadi, Albany, NY (US); Andrew Metz, Albany, NY (US)

(21) Appl. No.: 18/620,482

(22) Filed: Mar. 28, 2024

(51) Int. Cl. C23F 1/12; C09K 13/00; H01J 37/32; H01L 21/311

(52) U.S. Cl. CPC C23F 1/12; C09K 13/00; H01J 37/3244; H01L 21/31116; H01J 2237/334

(57) ABSTRACT

An example method for etching a barium containing layer includes patterning the barium containing layer, the patterning including exposing the barium containing layer to a carbon based ligand gas, the carbon based ligand gas reacting with the barium containing layer to form a barium containing product, and removing the barium containing product.

### TECHNICAL FIELD

The present disclosure relates generally to etching, and more particularly to methods for etching bi-metal oxides with alkaline earth metals.

### BACKGROUND

In the field of semiconductor fabrication, the etching process plays a pivotal role in shaping and defining the features of semiconductor devices. Etching is a technique used to remove layers from the surface of a wafer during manufacturing. An integral part of the process involves the use of specific gases that react with the material on the wafer surface, leading to its removal.

One of the materials often used in advanced memory device design and fabrication is barium titanate (BaTiO3), a common ferroelectric material. Barium titanate and similar perovskite materials are layered structures, with alternating layers containing barium and titanium. These materials are considered promising candidates for novel ferroelectric and photonic materials due to their advantageous properties.

However, the etching of these materials, particularly barium titanate, presents a challenge. The current state of the art for etching barium titanate and similar materials is halogen-based, using gases such as chlorine (Cl2), boron trichloride (BCl3), and fluorine (F2). These methods often rely on sputtering of the barium component to achieve etch, which can be detrimental to mask selectivity and roughness. Furthermore, the etching process can alter the material properties such that the etch rate decreases with exposure, limiting the ability for these materials to be easily integrated into ferroelectric devices at a high volume manufacturing level.

### SUMMARY

In an embodiment, a method for etching a barium containing layer includes patterning the barium containing layer, the patterning including exposing the barium containing layer to a carbon based ligand gas, the carbon based ligand gas reacting with the barium containing layer to form a barium containing product, and removing the barium containing product.

In an embodiment, a method for etching a barium containing layer includes performing a cyclic etching process to subtractively etch the barium containing layer, each cycle of the cyclic etching process including: exposing the barium containing layer to a carbon based ligand gas, the carbon based ligand gas reacting with the barium containing layer to form a barium containing product; and removing the barium containing product.

In an embodiment, a method for etching a bi-metal oxide layer includes patterning the bi-metal oxide layer containing an alkaline earth metal and a transition metal, the patterning including performing a cyclic process, each cycle of the cyclic process including: exposing the bi-metal oxide layer to a ligand gas to form a first volatile product including a ligand from the ligand gas and the alkaline earth metal; and exposing the bi-metal oxide layer to a reactive gas to form a second volatile product including atoms from the reactive gas and the transition metal; and volatilizing the first volatile product and the second volatile product to etch a portion of the bi-metal oxide layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A illustrates a cross-sectional view of a substrate with a blanket bi-metal oxide layer in accordance with an embodiment;

FIG. 1B illustrates a cross-sectional view of a semiconductor structure during fabrication after forming a metal rich region in accordance with an embodiment;

FIG. 1C illustrates a cross-sectional view of a semiconductor structure during fabrication after forming a ligand rich surface in accordance with an embodiment;

FIG. 1D illustrates a cross-sectional view of a semiconductor structure during fabrication after removing a barium containing product in accordance with an embodiment;

FIG. 1E illustrates a cross-sectional view of the substrate structure after patterning the bi-metal oxide layer in accordance with an embodiment;

FIGS. 2A-2B describes one cycle of etching a bi-metal layer in accordance with an embodiment;

FIGS. 3A-3B describes one cycle of etching a bi-metal layer using two different ligand gases in accordance with an embodiment;

FIGS. 4A-4B describes one cycle of etching a bi-metal layer using two different ligand gases followed by a common volatilization step in accordance with an embodiment;

FIG. 5 illustrates a flow chart of patterning a bi-metal layer in accordance with an embodiment;

FIG. 6 illustrates a flow chart of patterning a bi-metal layer in accordance with an embodiment; and

FIG. 7 illustrates a flow chart of patterning a bi-metal layer in accordance with an embodiment.

### DETAILED DESCRIPTION OF ILLUSTRATIVE EMBODIMENTS

The following disclosure provides many different examples for implementing different features. Specific examples of components and arrangements are described below to simplify the present disclosure. These are, of course, merely examples and are not intended to be limiting.

The present disclosure relates to methods for processing substrates, particularly to the etching of oxides of alkaline earth metals such as barium perovskite. In the field of advanced memory device design and fabrication, new materials are continually being explored to replace conventional materials. Barium titanate (BaTiO3) and similar perovskite materials are seen as promising candidates for novel ferroelectric and photonic materials. However, a challenge arises in the etching of these materials, particularly when using a halogen-based plasma process, due to the low volatility of possible etch products such as fluorides and chlorides.

The disclosed methodologies address the challenge by introducing an etching technique that does not rely primarily on halogen chemistry for the etching of alkaline earth metal oxides. This approach is anticipated to yield reaction pathways that are more favorable thermodynamically and produce etch products that are more volatile. Although certain implementations in this disclosure use barium titanate as an example, the etching methods outlined herein are broadly applicable to a variety of barium oxides and, more expansively, to oxides of alkaline earth metals, including complex oxides composed of alkaline-earth metals in combination with other metals.

The proposed methods involve the use of a carbon-based ligand system, such as hexafluoro(acac), to chelate e.g., barium ions in the barium oxides and create a volatile product that can be removed easily. This approach can potentially overcome the challenges associated with etching these metal oxides, thereby enabling their applications in advanced logic and memory devices.

In addition to the above, the disclosure also proposes several cyclic processes for etching a barium containing layer. These processes involve exposing the barium containing layer to a carbon-based ligand gas, which reacts with the layer to form a barium containing product. This product is then removed through various methods such as ion bombardment, plasma process, or annealing.

As discussed in more detail below, the present disclosure provides methods for etching barium-containing layers in a manner that is compatible with semiconductor fabrication processes. These methods provide potential options to overcome the difficulties encountered in etching barium titanate and related materials, thus enabling their incorporation into memory devices such ferroelectric memories.

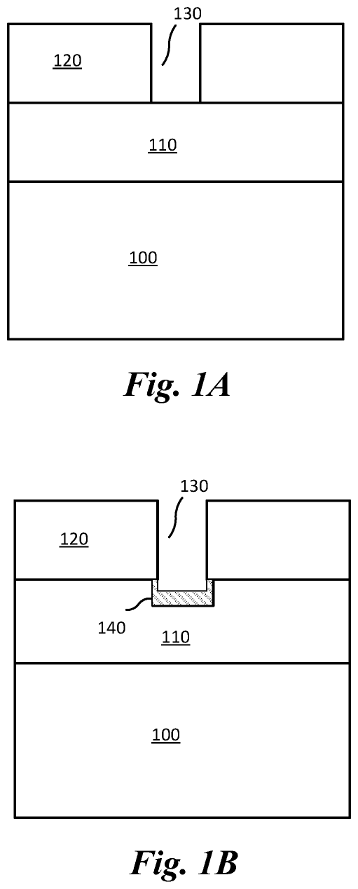

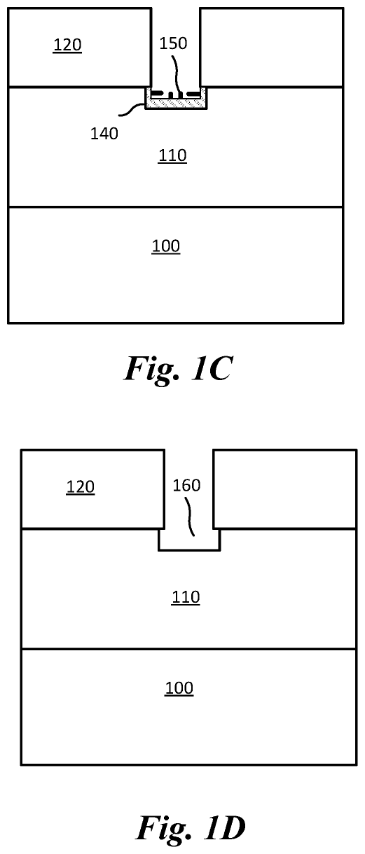

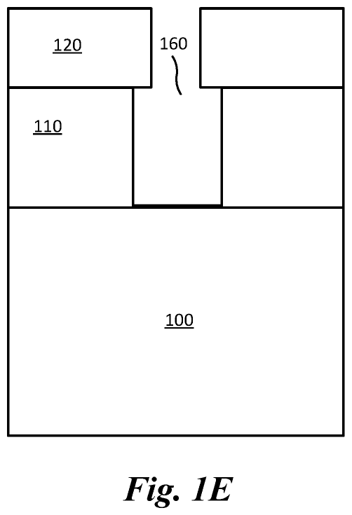

In the following, patterning an alkaline earth metal oxide layer such as barium containing oxide layer is described referring to FIGS. 1A-1E in accordance with various embodiments.

FIG. 1A illustrates a cross-sectional view of a substrate with a blanket bi-metal oxide layer in accordance with an embodiment.

In FIG. 1A, a bi-metal oxide layer 110 is formed over a substrate 100. A mask layer 120 is formed over the bi-metal oxide layer 110 and patterned to form an opening 130.

The substrate 100 referred to in the present disclosure is a semiconductor substrate, which may include various devices such as transistors, capacitors, and interconnects.

These devices are integral to the functionality of semiconductor chips used in a wide range of electronic applications, from simple logic gates to complex microprocessors, memory arrays, photonic devices. The substrate 100 may be composed of a semiconductor material such as silicon, silicon carbide, gallium arsenide, gallium nitride, indium arsenide, or other semiconductor materials known in the art. The substrate 100 may be doped to form various electronic devices and may include multiple layers of different materials that have been deposited or grown on its surface. The substrate 100 may include dielectric and metallization layers formed over a semiconductor substrate.

The substrate 100 may be a layered structure and provides the structural support for the deposition of various layers and the formation of electronic devices. The substrate 100 is the base upon which the bi-metal oxide layer 110 is deposited. In the case of forming a capacitor, such as FeRAM capacitor, this substrate may include a patterned bottom electrode on which the bi-metal oxide layer 110 may be deposited.

In various embodiments, the bi-metal oxide layer 110 comprises at least one alkaline earth metal such as barium and another metal, e.g., a transition metal such as titanium. In an example implementation, the bi-metal oxide layer 110 may comprise barium titanate (BaTiO3) or other similar perovskite materials, which are known for their ferroelectric properties and high-k dielectric properties.

The bi-metal oxide layer 110 may be deposited through methods such as chemical vapor deposition (CVD), physical vapor deposition (PVD), or atomic layer deposition (ALD). After deposition, an annealing step may be performed to achieve the appropriate crystal structure and ferroelectric properties.

The embodiments further describe etching methods to pattern this bi-metal oxide layer 110.

A mask layer 120 is formed over the bi-metal oxide layer 110. The mask layer 120 may be a hard mask and provides a protective barrier over areas of the bi-metal oxide layer 110 that are not intended to be etched, thereby defining the pattern that will be transferred onto the substrate. The mask layer 120 is used to define the regions where etching will occur and is patterned to create one or more openings 130. These openings 130 expose portions of the underlying bi-metal oxide layer 110 to the etching process, allowing for the selective removal of material to create the desired patterns on the substrate 100.

The formation of the mask layer 120 involves depositing a material that is resistant to the etching process. Materials commonly used for hard masks include silicon nitride, silicon oxide, or metal nitrides, among others. The choice of material depends on the etching selectivity, the compatibility with the underlying layers, and the specific requirements of the semiconductor device being fabricated.

Once the hard mask material is deposited, it is subjected to a photolithography process. This process begins with the application of a photoresist layer over the hard mask material. The photoresist is a light-sensitive polymer that changes its chemical structure when exposed to ultraviolet (UV) light. The substrate is then exposed to UV light through a photomask, which contains the desired pattern. The areas of the photoresist that are exposed to the light become soluble (in the case of a positive photoresist) or insoluble (in the case of a negative photoresist) to a developer solution.

After exposure, the substrate is developed to remove the soluble regions of the photoresist, revealing the underlying hard mask material. An etching process, such as reactive ion etching (RIE), is then used to transfer the pattern from the photoresist into the hard mask layer, creating the openings 130. The remaining photoresist is stripped away, leaving the patterned mask layer 120 ready to define the etching regions on the bi-metal oxide layer 110.

FIG. 1B illustrates a cross-sectional view of a semiconductor structure during fabrication after forming a metal rich region in accordance with an embodiment.

Referring to FIG. 1B, a first metal rich region 140 is formed by exposing the bi-metal oxide layer 110 to a halogen rich plasma. When the bi-metal oxide layer 110 comprises barium (first metal) and titanium (second metal), exposing to a halogen rich plasma may cause the formation of volatile titanium halides. The remaining surface may become rich in barium and thus form the first metal rich region 140. As the first metal rich region 140 becomes progressively more barium rich with exposure time with the halogen rich plasma, the barium rich first metal rich region 140 reduces the etching rate and hence this reaction is similar to a self-limiting reaction.

In some implementations, various halogen based gases may be utilized to etch a titanium portion of the bi-metal oxide layer 110. These gases can include, but are not limited to, chlorine (Cl₂), bromine (Br₂), or fluorine (F₂), as well as compounds like hydrogen chloride (HCl), hydrogen bromide (HBr), or hydrogen fluoride (HF), sulfur hexafluoride (SF6), nitrogen trifluoride (NF3), and carbon tetrafluoride (CF4). Each of these gases can be used alone or in combination with other gases to create a plasma that effectively removes titanium oxide by forming volatile byproducts. For instance, sulfur hexafluoride and nitrogen trifluoride can provide fluorine radicals that react with titanium oxide to form volatile titanium fluorides. Carbon tetrafluoride, on the other hand, can serve as a source of both carbon and fluorine, which can facilitate the removal of titanium oxide by forming volatile compounds. The selection of the plasma gas or gas mixture can be optimized based on the specific etching requirements, such as etch rate, selectivity, and the desired etch profile.

FIG. 1C illustrates a cross-sectional view of a semiconductor structure during fabrication after forming a ligand rich surface in accordance with an embodiment.

FIG. 1C illustrates a substrate that has undergone further surface treatment to form a first ligand rich surface 150 within a first metal rich region 140.

During this step, the substrate 100 may be exposed to a carbon based ligand gas. This carbon based ligand gas may react with the barium containing layer to form a barium containing product that is more volatile and thus easier to remove than the products formed using traditional halogen-based etching methods.

The composition of the carbon based ligand gas is carefully selected to optimize the surface adsorption process and creation of volatile products. The gas typically comprises organic compounds that contain carbon atoms capable of forming strong bonds with the barium atoms in the layer being etched. These ligands are chosen based on their ability to chelate the barium and form a complex that can be volatilized and removed from the substrate surface. The carbon based ligand gas may include, but is not limited to, a β-diketone such as hexafluoroacetylacetone (hexafluoro(acac)), a derivative of acetylacetone; a 2,4-diketo ester such as perfluoroethyl trifluoroacetoacetate; an aromatic cyclic polyene or polyene ion, such as cyclopentadienide; any of various amines, diamines, or polydentate amines, including porphyrins; any of various ethers, crown ethers, aza-crown ethers, or cryptands; or a cavitand such as any of the cucurbiturils; or combinations thereof. Each of these ligands offers a different mechanism for reacting with the barium, and they can be used alone or in combination to achieve the desired etching characteristics, such as selectivity, rate, and profile.

Hexafluoro(acac) is a ligand that can form volatile complexes with barium due to its strong chelating ability and the presence of fluorine atoms, which can enhance the volatility of the resulting product. Hexafluoro(acac) tautomerizes to an enol form in gas phase that can chelate with barium ions. (Another β-diketone with similar barium-ligating properties is 1,1,1,2,2,3,3,7,7,8,8,9,9,9-tetradecafluoro-4,6-nonanedione.) The barium containing byproduct may sublime at about 200° C. to 250° C. at atmospheric pressures or at lower temperature (e.g., about 100° C. to 150° C.) at sub-atmospheric pressures. The temperature may be further lowered with the introduction of additional processes such an ion bombardment. Aromatic cyclic polyenes and polyene ions are flat hydrocarbon rings with delocalized electrons that may chelate barium, including cyclopentadienide, benzene, tropylium cation, and cyclooctatetraendiide. Amines and diamines are nitrogen-containing organic compounds that can also coordinate with barium, while ethers provide oxygen atoms that can interact with the metal. Amines may include primary amines such as methylamine (CH₃NH₂), secondary amines like dimethylamine ((CH₃)₂NH), and tertiary amines such as trimethylamine ((CH₃)₃N). Diamines, which contain two amine groups, may include ethylenediamine (C₂H₈N₂), its carboxylic acid derivative ethylenediaminetetraacetic acid (EDTA), or hexamethylenediamine (C₆H₁₆N₂). Polydentate amines include triamines such as N,N,N′,N″,N″-pentamethyldiethylenetriamine and porphyrins such as porphine may coordinate with the barium three or more times. Ethers, such as diethyl ether (C₄H₁₀O) or tetrahydrofuran (C₄H₈O), provide oxygen atoms that can interact with barium. Polydentate cyclic ethers or “crown ethers” are so called because of their puckered structure, which resembles a crown. Examples include 12-crown-4, 15-crown-5, 18-crown-6, or dibenzo-18-crown-6, all of which may coordinate with the barium multiple times. Aza-crown ethers such as 4,13-diaza-18-crown-6 include a mix of amine and ether function, while cryptands such as [2.2.2]cryptand are three-dimensional rather than puckered. Other three-dimensional, basket- or container-shaped molecules are called cavitands and may also be multifunctional ligands for barium; a family of cavitands that could be used for this purpose are the cucurbiturils, such as cucurbit[6]uril. The use of these carbon based ligands represents a novel approach to etching barium containing layers, offering a more controlled and efficient process that is compatible with the stringent requirements of semiconductor device fabrication.

FIG. 1D illustrates a cross-sectional view of a semiconductor structure during fabrication after removing a barium containing product in accordance with an embodiment.

FIG. 1D shows the substrate after further processing to form an etched region 160. In this step, the barium containing product may be removed. This removal may be achieved by exposing the barium containing layer to an ion bombardment process, or exposing the barium containing layer to a plasma process, or annealing the barium containing layer. In some aspects, the annealing temperature may be reasonable, e.g., 50° C. to 200° C., which is much lower than the temperatures that would be typically be used if a halogen chemistry were to be used. In some implementations, the chuck temperature may be raised during the barium surface removal step to facilitate byproduct leaving the surface. This approach may provide a more efficient etching process, enabling the integration of barium-containing layers into advanced memory devices.

In some cases, removing the barium containing layer completes one cycle of a cyclic process described in FIGS. 1B-1D. This cyclic process may involve performing a cyclic etching process to subtractively etch the barium containing layer. Each cycle of the cyclic etching process may comprise enriching the surface to be barium rich by removing titanium, e.g., using a halogen based chemistry discussed with respect to FIG. 1B, exposing the barium containing layer to a carbon based ligand gas to form a barium containing product as discussed with respect to FIG. 1C, and removing the barium containing product discussed with respect to FIG. 1D.

In some aspects, each cycle of the cyclic etching process may further comprise exposing the barium containing layer to a halogen containing gas. In other cases, the bi-metal oxide layer 110 may be exposed to a carbon based ligand gas and to a halogen based gas sequentially as part of a cyclic process until the bi-metal oxide layer 110 is patterned. The patterning of the bi-metal oxide layer 110 may comprise removing the bi-metal oxide layer 110 using an annealing process or an inert plasma process.

FIG. 1E illustrates a cross-sectional view of the substrate structure after patterning the bi-metal oxide layer in accordance with an embodiment.

Referring to FIG. 1E, a series of cycles may be performed until all of the bi-metal oxide layer 110 is etched and the underlying substrate 100 is exposed. The number of cycles may be determined using an endpoint detection method or may be timed. Any remaining mask layer 120 may be removed.

Subsequent processing may follow based on the device being formed. For example, in case a FeRAM memory is being formed, after patterning, a top electrode may be deposited over the ferroelectric patterned bi-metal layer. The top electrode material may be a conductive material compatible with ferroelectric materials. The completed ferroelectric capacitor structure with top and bottom electrodes encapsulating the patterned bi-metal layer may then be integrated into the broader semiconductor device architecture, which includes circuitry for addressing, reading, and writing to individual memory cells.

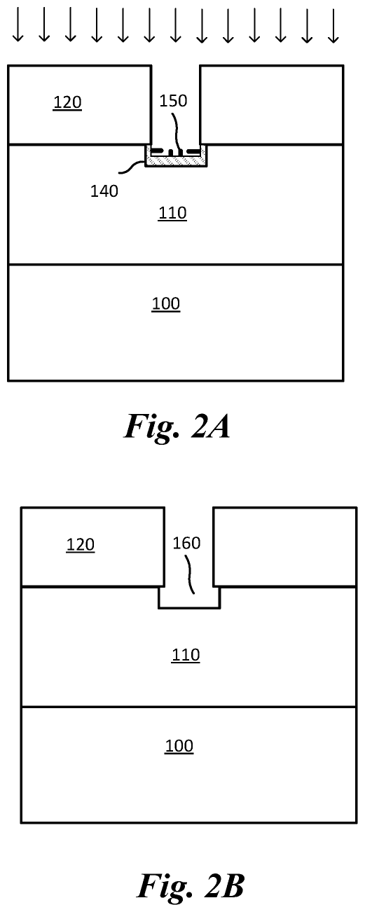

FIGS. 2A-2B describes one cycle of etching a bi-metal layer in accordance with an embodiment. FIGS. 2A-2B represent one cycle of a cyclic process.

Referring to FIG. 2A, a simultaneous etching process is depicted wherein the bi-metal oxide layer 110 is concurrently exposed to both a carbon based ligand gas and a halogen based gas. Thus, after the first step in this cycle, the surface of the bi-metal oxide layer 110 includes a first metal rich region 140 and a first ligand rich surface 150. This simultaneous exposure facilitates a synergistic reaction where the halogen based gas reacts with the titanium and oxygen components of the bi-metal oxide layer 110 to form volatile titanium halides, while the carbon based ligand gas reacts with the barium component to form a barium containing product. The concurrent exposure to both gases enables the formation of reaction products that are more volatile and thus more readily removed from the substrate surface, leading to an efficient and controlled etching process.

The simultaneous etching process is designed to leverage the distinct reactivity of the carbon based ligand gas and the halogen based gas to achieve a high degree of selectivity and an increased etch rate. The carbon based ligand gas, which may have a composition like that described for previous embodiments, specifically targets the barium atoms in the layer, forming a complex that can be volatilized. Meanwhile, the halogen based gas, which may include chlorine, fluorine, or other halogens, reacts with the titanium and oxygen to form volatile titanium halides.

The gas compositions used in the etching process are tailored to interact with the different components of the bi-metal oxide layer 110. For the halogen based gas, the composition may include gases such as chlorine (Cl₂), bromine (Br₂), or fluorine (F₂), as well as compounds like hydrogen chloride (HCl), hydrogen bromide (HBr), or hydrogen fluoride (HF). These gases are selected for their ability to react with titanium and oxygen to form volatile halides, such as titanium tetrachloride (TiCl₄) or titanium tetrafluoride (TiF₄), which can be efficiently removed from the substrate surface.

For the carbon based ligand gas, the composition may include a variety of organic compounds that can form strong bonds with barium. Hexafluoroacetylacetone (hexafluoro(acac)) is a fluorinated β-diketone that can chelate barium to form volatile complexes. Amines may include primary amines such as methylamine (CH₃NH₂), secondary amines like dimethylamine ((CH₃)₂NH), and tertiary amines such as trimethylamine ((CH₃)₃N). Diamines, which contain two amine groups, may include ethylenediamine (C₂H₈N₂) or hexamethylenediamine (C₆H₁₆N₂). Ethers, such as diethyl ether (C₄H₁₀O) or tetrahydrofuran (C₄H₈O), provide oxygen atoms that can interact with barium. These carbon based ligands can be used individually or in combinations to optimize the etching process for selectivity, rate, and profile.

While treating the surface with the halogen chemistry and the carbon based ligand gas, the barium rich product may be volatilized. In some embodiments, the volatilization may be performed after surface treatment processes. As discussed in prior embodiments, this may be accomplished by ion bombardment or annealing process, and other suitable methods. For example, in some implementations, a plasma containing gases such as Ar, He, Kr, Xe, etc may be used to provide ion assistance to remove the barium containing byproduct.

FIG. 2B illustrates a cross-sectional view after the barium rich product is volatilized.

The concurrent use of these gas compositions in the simultaneous etching process allows for the selective removal of titanium and barium from the bi-metal oxide layer 110, resulting in a patterned structure that is suitable for the fabrication of advanced semiconductor devices.

This dual-gas approach allows for the precise patterning of the bi-metal oxide layer 110, as the volatile products formed from the reactions are efficiently removed, leaving behind a patterned surface that corresponds to the openings 130 in the mask layer 120. The simultaneous etching process thus represents a novel method for processing barium-containing layers, offering improved outcomes in terms of efficiency.

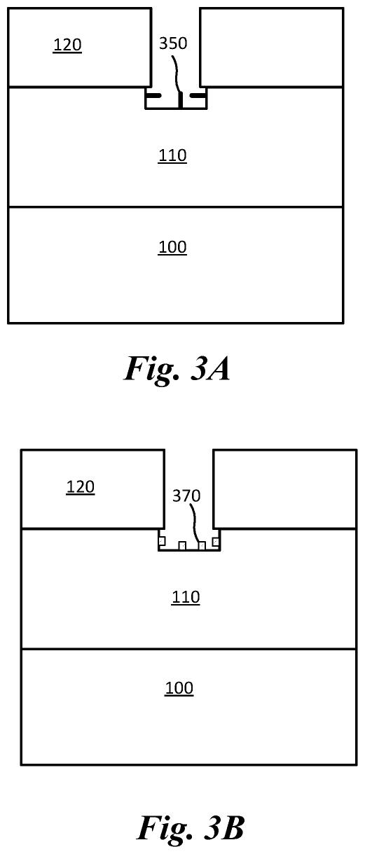

FIGS. 3A-3B describes one cycle of etching a bi-metal layer using two different gases in accordance with an embodiment. FIGS. 3A-3B represent one cycle of a cyclic process.

This embodiment uses two gases, one for each, for each of the metals in the bi-metal oxide layer. The first gas may be specifically selected for its reactivity with one component of the bi-metal oxide layer 110, while the second gas may be chosen for its reactivity with another component. For example, if the bi-metal oxide layer 110 comprises titanium and barium, the first gas may preferentially react with titanium to form a volatile titanium complex, while the second gas may react with barium to form a volatile barium complex. The order of exposure may be changed in different embodiments.

Referring to FIGS. 3A, in the first step of the cycle, the substrate is exposed to a first gas, e.g., a reactive gas, which forms a product rich in the first metal. For example, in one embodiment, when the bi-metal oxide layer 110 comprises barium and titanium, the first gas, e.g., a reactive gas, may be selected to preferentially attach with titanium atoms creating a first metal rich surface 350 on the bi-metal oxide layer 110. In other words, the bi-metal oxide layer 110 is exposed to a first gas, which reacts with the layer to form a first byproduct. This first byproduct can then be volatilized, e.g., by ion bombardment in a gentle plasma or by annealing. For example, the surface of the bi-metal oxide layer 110 may be bombarded with a low power plasma made from an inert gas in one embodiment.

In one embodiment, the first gas may be a halogen based gas such as chlorine (Cl₂), bromine (Br₂), or fluorine (F₂), as well as compounds like hydrogen chloride (HCl), hydrogen bromide (HBr), or hydrogen fluoride (HF), sulfur hexafluoride (SF6), nitrogen trifluoride (NF3), and carbon tetrafluoride (CF4). Embodiments may also use a plasma generated from one or more of the above gases such as CF4.

In some various embodiments, the first gas may comprise a ligand gas with a composition like that described for previous embodiments. The volatile byproducts formed may include Titanium (IV) chloride (TiCl4) with conjunction to ligands that will make it less reactive and more volatile, such as Tetrakis(dimethylamino)titanium (TDMAT), Tetrakis(diethylamino)titanium (TDEAT).

Subsequently, as illustrated in FIG. 3B, a second gas is introduced, reacting with the remaining material in the bi-metal oxide layer 110 to form a second byproduct. In one embodiment, the second gas may be a ligand gas that chelates the second metal. This second byproduct is also volatilized, potentially forming a ligand rich surface 370, which may be on the opposite side of the bi-metal oxide layer 110 or in a different region of the substrate structure. Similarly, this second byproduct can then be volatilized, e.g., by ion bombardment in a gentle plasma or by annealing. For example, the surface of the bi-metal oxide layer 110 may be bombarded with a low power plasma made from an inert gas in one embodiment. In this embodiment, the volatilization process may be selected so as to best remove each of the first and second byproducts effectively without introducing damage to the remaining layers.

In various embodiments, the second gas is a carbon based ligand that preferentially attaches to barium atoms, and similar to the ligands discussed in prior embodiments.

The sequential use of two distinct gases allows for a more nuanced etching process, where each metal component of the bi-metal oxide layer 110 can be selectively and efficiently removed. In an embodiment, the volatilization of the first and second byproducts is facilitated by the different ligand gases' ability to form complexes with the respective metal components that are more volatile than the original metal oxides. This increased volatility enables the byproducts to be removed from the substrate surface at lower temperatures or with less aggressive etching conditions, which can be beneficial for preserving the integrity of the mask layer 120 without introducing etching defects.

In various embodiments, the cyclic nature of this etching process allows for the precise control of the etching depth and profile. By repeating the cycles of exposure to the first and second gases, followed by the volatilization of the respective byproducts, the bi-metal oxide layer 110 can be etched to the desired specifications. In various embodiments, the number of cycles and the duration of gas exposure can be adjusted based on the thickness of the bi-metal oxide layer 110, the desired etch rate, and the etching selectivity requirements of the specific application. In certain applications for etching a bi-metal oxide layer 110 containing barium and titanium, the bi-metal oxide layer 110 may be exposed to volatize barium followed by volatizing titanium.

This dual reactant approach, e.g., a dual-ligand gas approach provides a versatile and efficient method for etching complex bi-metal oxide layers, such as those containing barium and titanium, and is particularly advantageous for the fabrication of advanced semiconductor devices where precise patterning and material selectivity are of utmost concern.

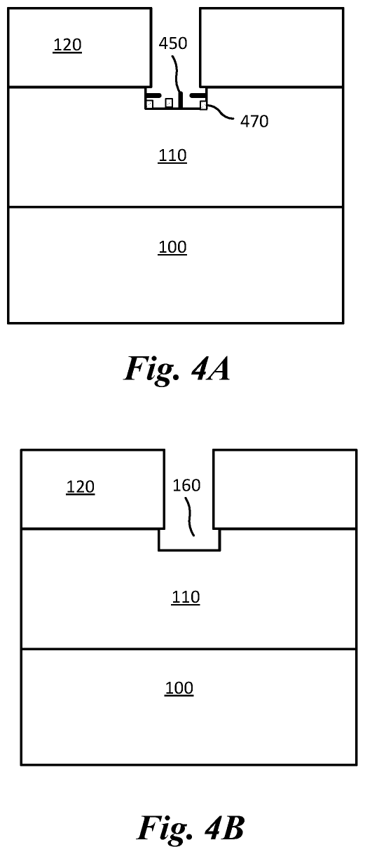

FIGS. 4A-4B describes one cycle of etching a bi-metal layer using two different ligand gases followed by a common volatilization step in accordance with an embodiment. FIGS. 4A-4B represent one cycle of a cyclic process.

During the etching cycle depicted in FIGS. 4A-4B, the bi-metal oxide layer 110 is exposed to a gas, which may react simultaneously with the two metals, e.g., barium and titanium, to form a respective volatile complex. In one or more embodiments, a single ligand gas may be able to react with each of the two metals, e.g., barium and titanium, to form a respective volatile complex. Such a dual acting ligand gas may have a composition like that described for previous embodiments. The ligand gas may include the specific examples provided above with respect to FIGS. 1C and 2A. For example, β-diketones such as hexafluoroacetylacetone (hexafluoro(acac)), and other acac may be able to chelate with both the metals, e.g., barium and titanium, to form a respective volatile complex.

In some implementations, two different ligand gases such as a first ligand gas and a second ligand gas may be introduced into the processing chambers simultaneously or sequentially. In some various embodiments, the first ligand gas may include, but is not limited to, a β-diketone such as hexafluoroacetylacetone (hexafluoro(acac)), a derivative of acetylacetone; a 2,4-diketo ester such as perfluoroethyl trifluoroacetoacetate; an aromatic cyclic polyene or polyene ion, such as cyclopentadienide, which forms the complex titanium tetrakis(cyclopentadienide) (Ti(Cp)4); any of various amines, diamines, or polydentate amines, including porphyrins; any of various ethers, crown ethers, aza-crown ethers, or cryptands; or a cavitand such as any of the cucurbiturils; or combinations thereof. Each of these ligands offers a different mechanism for reacting with the titanium, and they can be used alone or in combination to achieve the desired etching characteristics, such as selectivity, rate, and profile. The first ligand gas may also comprise isopropyl alcohol, which has alkoxy groups capable of chelating the titanium and forming titanium tetra-isopropoxide (TTIP). The second ligand gas may have a composition like that described for previous embodiments. The second ligand gas may include the specific examples provided above with respect to FIGS. 1C and 2A.

Irrespective of having a single ligand gas or a dual ligand gas mixture, this reaction creates a first ligand rich surface 450 and a second ligand rich surface 470.

Following this, referring to FIG. 4B, the volatilization of these complexes results in the formation of the etched region 160, which represents the removal of both metals and oxygen, e.g., barium and titanium components from the bi-metal oxide layer 110.

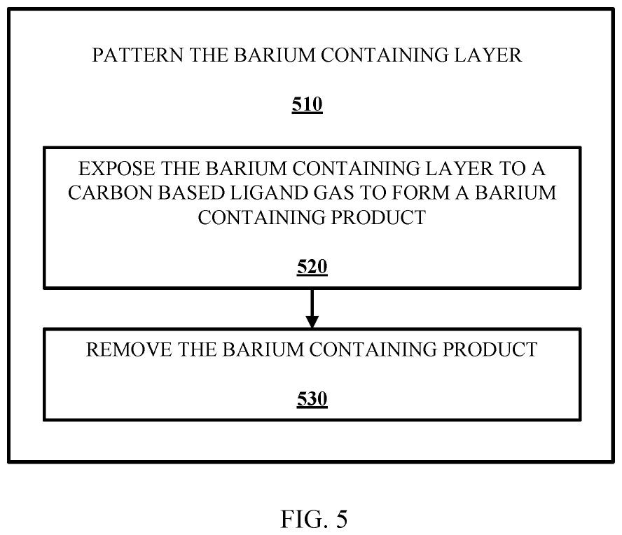

FIG. 5 illustrates a flow chart of patterning a bi-metal layer in accordance with an embodiment.

In one embodiment, a method for etching a barium containing layer includes patterning the barium containing layer (box 510). The patterning may include exposing the barium containing layer to a carbon based ligand gas (box 520). The carbon based ligand gas may react with the barium containing layer to form a barium containing product. The method also includes and removing the barium containing product (box 530).

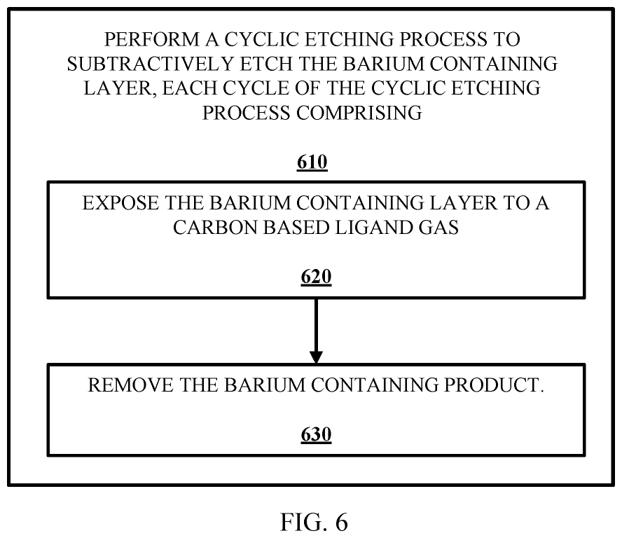

FIG. 6 illustrates a flow chart of patterning a bi-metal layer in accordance with an embodiment.

In one embodiment, a method for etching a barium containing layer includes performing a cyclic etching process to subtractively etch the barium containing layer (box 610). Each cycle of the cyclic etching exposing the barium containing layer to a carbon based ligand gas (box 620), the carbon based ligand gas reacting with the barium containing layer to form a barium containing product. Each cycle also includes removing the barium containing product (box 630).

The flow charts described in FIGS. 5-6 may be implemented, for example, as described in more detail using FIGS. 1A-1E, 2A-2B, 3A-3B, 4A-4B.

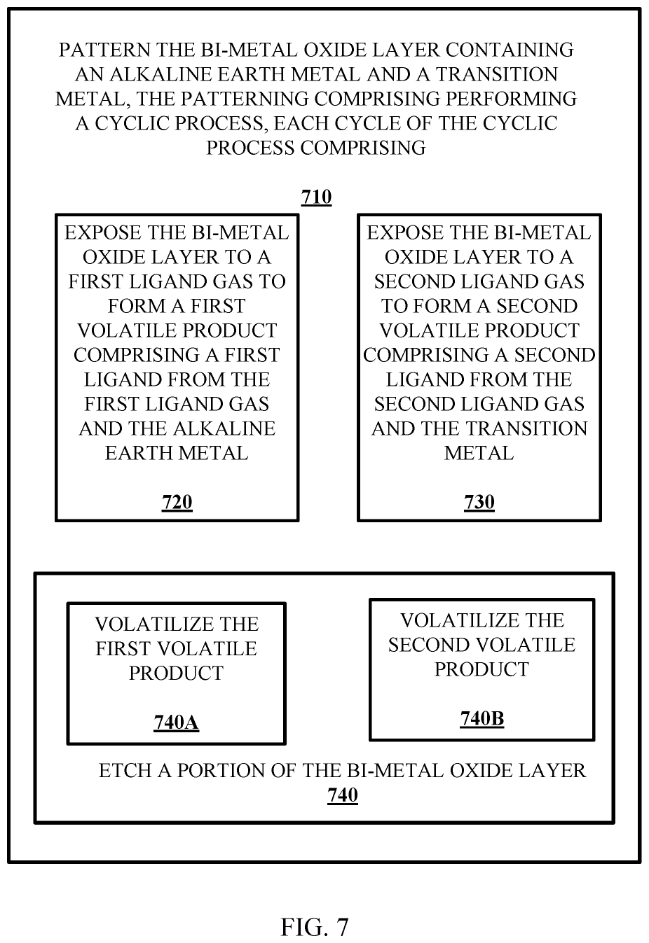

FIG. 7 illustrates a flow chart of patterning a bi-metal layer in accordance with an embodiment.

In one embodiment, a method for etching a bi-metal oxide layer includes patterning the bi-metal oxide layer containing an alkaline earth metal and a transition metal (box 710), the patterning may include performing a cyclic process. Each cycle of the cyclic process includes exposing the bi-metal oxide layer to a first ligand gas to form a first volatile product including a first ligand from the first ligand gas and the alkaline earth metal (box 720). Each cycle also includes exposing the bi-metal oxide layer to a second ligand gas to form a second volatile product including a second ligand from the second ligand gas and the transition metal (box 730). Each cycle also includes volatilizing the first volatile product (box 740A) and the second volatile product (box 740B) to etch a portion of the bi-metal oxide layer (box 740). The volatilizing the first volatile product and the second volatile product may be performed together or in some embodiments sequentially. For example, the first volatile product may be volatilized prior to exposing to the second ligand gas. As discussed above, the volatilizing may include annealing, implantation, ion bombardment, exposure to plasma, and others.

The flow charts described in FIGS. 5-6 may be implemented, for example, as described in more detail using FIGS. 4A-4B.

Embodiments of this process may be applied to fabricating various types of devices. Barium titanate (BaTiO3) is used in the production of ferroelectric random-access memory (FRAM or FeRAM) due to its ferroelectric properties. In these memory devices, barium titanate serves as the dielectric material that can store information in the form of electric polarization states. In ferroelectric materials like barium titanate, the unit cell of the crystal structure exhibits a spontaneous electric polarization that can be reversed by the application of an external electric field. This polarization arises because the center of positive charge and the center of negative charge within the cell are slightly offset, which creates a dipole moment. A typical FRAM memory cell includes a ferroelectric capacitor connected to a transistor. The ferroelectric material, such as barium titanate produced as described in various embodiments in this disclosure, is sandwiched between two electrodes to form the capacitor. The transistor is used to access the capacitor during read and write operations. Data is stored by applying an electric field to the ferroelectric capacitor, which causes its dipoles to align in one direction or the other, corresponding to a binary “1” or “0” state. The ferroelectric nature of barium titanate allows it to retain this polarization state even after the external electric field is removed, making it a non-volatile memory. To read data, a voltage pulse is applied to the capacitor. If the polarization state of the material is opposite to that of the applied pulse, a charge will flow as the dipoles switch orientation. This charge can be detected as a “1.” If no charge flows, it means that the dipoles were already aligned with the pulse, indicating a “0.” The data is thus read by detecting the presence or absence of this charge. Writing data involves applying an electric field in the desired direction to set the state to “1” or “0.” The ability of barium titanate to maintain its polarization until another field is applied allows the FRAM to store data for long periods without power.

Example embodiments of the invention are described below. Other embodiments can also be understood from the entirety of the specification as well as the claims filed herein.

Example 1. A method for etching a barium containing layer includes patterning the barium containing layer, the patterning including exposing the barium containing layer to a carbon based ligand gas, the carbon based ligand gas reacting with the barium containing layer to form a barium containing product, and removing the barium containing product.

Example 2. The method of example 1, where removing the barium containing product includes exposing the barium containing layer to an ion bombardment process.

Example 3. The method of one of examples 1 or 2, where removing the barium containing product includes exposing the barium containing layer to a plasma process.

Example 4. The method of one of examples 1 to 3, where removing the barium containing product includes annealing the barium containing layer.

Example 5. The method of one of examples 1 to 4, where the barium containing layer includes titanium, where the patterning including exposing the barium containing layer to a halogen containing gas.

Example 6. The method of one of examples 1 to 5, where the carbon based ligand gas includes β-diketones, 2,4-diketo esters, aromatic cyclic polyenes or polyene ions, amines, diamines, polydentate amines, crown ethers, aza-crown ethers, cryptands, porphyrins, or cavitands

Example 7. The method of one of examples 1 to 6, where the carbon based ligand gas includes hexafluoro acetylacetonate (hfacac), 1,1,1,2,2,3,3,7,7,8,8,9,9,9-tetradecafluoro-4,6-nonanedione, acetylacetone, perfluoroethyl trifluoroacetoacetate, cyclopentadienide, benzene, tropylium cation, cyclooctatetraendiide, methylamine, dimethylamine, trimethylamine, ethylenediamine, ethylenediaminetetraacetic acid, hexamethylenediamine, N,N,N′,N″,N″-pentamethyldiethylenetriamine, porphine, diethyl ether, tetrahydrofuran, 12-crown-4, 15-crown-5, 18-crown-6, dibenzo-18-crown-6, 4,13-diaza-18-crown-6, [2.2.2]cryptand, or cucurbit[6]uril.

Example 8. The method of one of examples 1 to 7, where the carbon based ligand gas includes a β-diketone, 2,4-diketo ester, aromatic cyclic polyene, a salt or complex including an aromatic cyclic polyene ion, amine, diamine, polydentate amine, porphyrin, crown ether, aza-crown ether, cryptand, cavitand, or cucurbituril.

Example 9. The method of one of examples 1 to 8, further includes exposing the barium containing layer to a halogen based gas while exposing the barium containing layer to a carbon based ligand gas, the barium containing layer including titanium and oxygen, the halogen based gas reacting with the titanium containing layer to form a titanium containing product.

Example 10. A method for etching a barium containing layer includes performing a cyclic etching process to subtractively etch the barium containing layer, each cycle of the cyclic etching process including: exposing the barium containing layer to a carbon based ligand gas, the carbon based ligand gas reacting with the barium containing layer to form a barium containing product; and removing the barium containing product.

Example 11. The method of example 10, where each cycle further includes exposing the barium containing layer to a halogen containing gas, the barium containing layer including titanium.

Example 12. The method of one of examples 10 or 11, where the barium containing layer includes titanium, where exposing the barium containing layer to a carbon based ligand gas further forms a titanium containing product, the method further including: removing the titanium containing product.

Example 13. The method of one of examples 10 to 12, where removing the barium containing product includes exposing the barium containing layer to an ion bombardment process.

Example 14. The method of one of examples 10 to 13, where removing the barium containing product includes exposing the barium containing layer to a plasma process.

Example 15. The method of one of examples 10 to 14, where removing the barium containing product includes annealing the barium containing layer.

Example 16. The method of one of examples 10 to 15, where the carbon based ligand gas includes hexafluoro(acac), amines, diamines, ethers, or combinations thereof.

Example 17. The method of one of examples 10 to 16, where the carbon based ligand gas includes hexafluoro acetylacetonate (hfacac), 1,1,1,2,2,3,3,7,7,8,8,9,9,9-tetradecafluoro-4,6-nonanedione, acetylacetone, perfluoroethyl trifluoroacetoacetate, cyclopentadienide, benzene, tropylium cation, cyclooctatetraendiide, methylamine, dimethylamine, trimethylamine, ethylenediamine, ethylenediaminetetraacetic acid, hexamethylenediamine, N,N,N′,N″,N″-pentamethyldiethylenetriamine, porphine, diethyl ether, tetrahydrofuran, 12-crown-4, 15-crown-5, 18-crown-6, dibenzo-18-crown-6, 4,13-diaza-18-crown-6, [2.2.2]cryptand, or cucurbit[6]uril.

Example 18. The method of one of examples 10 to 17, where the carbon based ligand gas includes a β-diketone, 2,4-diketo ester, aromatic cyclic polyene, a salt or complex including an aromatic cyclic polyene ion, amine, diamine, polydentate amine, porphyrin, crown ether, aza-crown ether, cryptand, cavitand, or cucurbituril.

Example 19. A method for etching a bi-metal oxide layer includes patterning the bi-metal oxide layer containing an alkaline earth metal and a transition metal, the patterning including performing a cyclic process, each cycle of the cyclic process including: exposing the bi-metal oxide layer to a ligand gas to form a first volatile product including a ligand from the ligand gas and the alkaline earth metal; and exposing the bi-metal oxide layer to a reactive gas to form a second volatile product including atoms from the reactive gas and the transition metal; and volatilizing the first volatile product and the second volatile product to etch a portion of the bi-metal oxide layer.

Example 20. The method of example 19, where exposing the bi-metal oxide layer to the ligand gas and the reactive gas is performed concurrently.

Example 21. The method of one of examples 19 or 20, where volatilizing the first volatile product and the second volatile product is performed concurrently.

Example 22. The method of one of examples 19 to 21, where volatilizing the first volatile product includes performing an annealing process.

Example 23. The method of one of examples 19 to 22, where volatilizing the first volatile product includes using an inert plasma process.

Example 24. The method of one of examples 19 to 23, where the alkaline earth metal includes barium and the transition metal includes titanium, where ligand gas includes hexafluoro acetylacetonate (hfacac), amines, diamines, ethers, or combinations thereof, where the reactive gas includes molecules including chlorine or fluorine.

Example 25. The method of one of examples 19 to 24, where the alkaline earth metal includes barium and the transition metal includes titanium, where ligand gas includes hexafluoro acetylacetonate (hfacac), 1,1,1,2,2,3,3,7,7,8,8,9,9,9-tetradecafluoro-4,6-nonanedione, acetylacetone, perfluoroethyl trifluoroacetoacetate, cyclopentadienide, benzene, tropylium cation, cyclooctatetraendiide, methylamine, dimethylamine, trimethylamine, ethylenediamine, ethylenediaminetetraacetic acid, hexamethylenediamine, N,N,N′,N″,N″-pentamethyldiethylenetriamine, porphine, diethyl ether, tetrahydrofuran, 12-crown-4, 15-crown-5, 19-crown-6, dibenzo-18-crown-6, 4,13-diaza-18-crown-6, [2.2.2]cryptand, or cucurbit[6]uril, where the reactive gas includes molecules including chlorine or fluorine.

Example 26. The method of one of examples 19 to 25, where the alkaline earth metal includes barium and the transition metal includes titanium, where ligand gas includes a β-diketone, 2,4-diketo ester, aromatic cyclic polyene, a salt or complex including an aromatic cyclic polyene ion, amine, diamine, polydentate amine, porphyrin, crown ether, aza-crown ether, cryptand, cavitand, or cucurbituril, where the reactive gas includes molecules including chlorine or fluorine.

Example 27. The method of one of examples 19 to 26, where the alkaline earth metal includes barium and the transition metal includes titanium, where ligand gas includes hexafluoro acetylacetonate (hfacac), amines, diamines, ethers, or combinations thereof, where the reactive gas includes β-diketones, cyclopentadienyl ligands, or combinations thereof.

Example 28. The method of one of examples 19 to 27, where the alkaline earth metal includes barium and the transition metal includes titanium, where ligand gas includes hexafluoro acetylacetonate (hfacac), 1,1,1,2,2,3,3,7,7,8,8,9,9,9-tetradecafluoro-4,6-nonanedione, acetylacetone, perfluoroethyl trifluoroacetoacetate, cyclopentadienide, benzene, tropylium cation, cyclooctatetraendiide, methylamine, dimethylamine, trimethylamine, ethylenediamine, ethylenediaminetetraacetic acid, hexamethylenediamine, N,N,N′,N″,N″-pentamethyldiethylenetriamine, porphine, diethyl ether, tetrahydrofuran, 12-crown-4, 15-crown-5, 19-crown-6, dibenzo-18-crown-6, 4,13-diaza-18-crown-6, [2.2.2]cryptand, or cucurbit[6]uril, where the reactive gas includes β-diketones, cyclopentadienyl ligands, or combinations thereof.

Example 29. The method of one of examples 19 to 28, where the alkaline earth metal includes barium and the transition metal includes titanium, where ligand gas includes a β-diketone, 2,4-diketo ester, aromatic cyclic polyene, a salt or complex including an aromatic cyclic polyene ion, amine, diamine, polydentate amine, porphyrin, crown ether, aza-crown ether, cryptand, cavitand, or cucurbituril, where the reactive gas includes β-diketones, cyclopentadienyl ligands, or combinations thereof.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for etching a barium containing layer, the method comprising:
patterning the barium containing layer, the patterning comprising
exposing the barium containing layer to a carbon based ligand gas, the carbon based ligand gas reacting with the barium containing layer to form a barium containing product, and
removing the barium containing product.

2. The method of claim 1, wherein removing the barium containing product comprises exposing the barium containing layer to an ion bombardment process.

3. The method of claim 1, wherein removing the barium containing product comprises exposing the barium containing layer to a plasma process.

4. The method of claim 1, wherein removing the barium containing product comprises annealing the barium containing layer.

5. The method of claim 1, wherein the barium containing layer comprises titanium, wherein the patterning comprising exposing the barium containing layer to a halogen containing gas.

6. The method of claim 1, wherein the carbon based ligand gas comprises β-diketones, 2,4-diketo esters, aromatic cyclic polyenes or polyene ions, amines, diamines, polydentate amines, crown ethers, aza-crown ethers, cryptands, porphyrins, or cavitand.

7. The method of claim 1, wherein the carbon based ligand gas comprises hexafluoro acetylacetonate (hfacac), 1,1,1,2,2,3,3,7,7,8,8,9,9,9-tetradecafluoro-4,6-nonanedione, acetylacetone, perfluoroethyl trifluoroacetoacetate, cyclopentadienide, benzene, tropylium cation, cyclooctatetraendiide, methylamine, dimethylamine, trimethylamine, ethylenediamine, ethylenediaminetetraacetic acid, hexamethylenediamine, N,N,N′,N″,N″-pentamethyldiethylenetriamine, porphine, diethyl ether, tetrahydrofuran, 12-crown-4, 15-crown-5, 18-crown-6, dibenzo-18-crown-6, 4,13-diaza-18-crown-6, [2.2.2]cryptand, or cucurbit[6]uril.

8. The method of claim 1, wherein the carbon based ligand gas comprises a β-diketone, 2,4-diketo ester, aromatic cyclic polyene, a salt or complex comprising an aromatic cyclic polyene ion, amine, diamine, polydentate amine, porphyrin, crown ether, aza-crown ether, cryptand, cavitand, or cucurbituril.

9. The method of claim 1, further comprising exposing the barium containing layer to a halogen based gas while exposing the barium containing layer to a carbon based ligand gas, the barium containing layer comprising titanium and oxygen, the halogen based gas reacting with the titanium containing layer to form a titanium containing product.

10. A method for etching a barium containing layer, the method comprising:
performing a cyclic etching process to subtractively etch the barium containing layer, each cycle of the cyclic etching process comprising:
exposing the barium containing layer to a carbon based ligand gas, the carbon based ligand gas reacting with the barium containing layer to form a barium containing product; and
removing the barium containing product.

11. The method of claim 10, wherein each cycle further comprises:
exposing the barium containing layer to a halogen containing gas, the barium containing layer comprising titanium.

12. The method of claim 10, wherein the barium containing layer comprises titanium, wherein exposing the barium containing layer to a carbon based ligand gas further forms a titanium containing product, the method further comprising:
removing the titanium containing product.

13. The method of claim 10, wherein removing the barium containing product comprises exposing the barium containing layer to an ion bombardment process, exposing the barium containing layer to a plasma process, or annealing the barium containing layer.

14. The method of claim 10, wherein the carbon based ligand gas comprises hexafluoro(acac), amines, diamines, ethers, or combinations thereof.

15. The method of claim 10, wherein the carbon based ligand gas comprises hexafluoro acetylacetonate (hfacac), 1,1,1,2,2,3,3,7,7,8,8,9,9,9-tetradecafluoro-4,6-nonanedione, acetylacetone, perfluoroethyl trifluoroacetoacetate, cyclopentadienide, benzene, tropylium cation, cyclooctatetraendiide, methylamine, dimethylamine, trimethylamine, ethylenediamine, ethylenediaminetetraacetic acid, hexamethylenediamine, N,N,N′,N″,N″-pentamethyldiethylenetriamine, porphine, diethyl ether, tetrahydrofuran, 12-crown-4, 15-crown-5, 18-crown-6, dibenzo-18-crown-6, 4,13-diaza-18-crown-6, [2.2.2]cryptand, or cucurbit[6]uril.

16. The method of claim 10, wherein the carbon based ligand gas comprises a β-diketone, 2,4-diketo ester, aromatic cyclic polyene, a salt or complex comprising an aromatic cyclic polyene ion, amine, diamine, polydentate amine, porphyrin, crown ether, aza-crown ether, cryptand, cavitand, or cucurbituril.

17. A method for etching a bi-metal oxide layer, the method comprising:
patterning the bi-metal oxide layer containing an alkaline earth metal and a transition metal, the patterning comprising performing a cyclic process, each cycle of the cyclic process comprising:
exposing the bi-metal oxide layer to a ligand gas to form a first volatile product comprising a ligand from the ligand gas and the alkaline earth metal; and
exposing the bi-metal oxide layer to a reactive gas to form a second volatile product comprising atoms from the reactive gas and the transition metal; and
volatilizing the first volatile product and the second volatile product to etch a portion of the bi-metal oxide layer.

18. The method of claim 17, wherein exposing the bi-metal oxide layer to the ligand gas and the reactive gas is performed concurrently.

19. The method of claim 17, wherein the alkaline earth metal includes barium and the transition metal includes titanium, where ligand gas includes hexafluoro acetylacetonate (hfacac), amines, diamines, ethers, or combinations thereof, and wherein the reactive gas includes molecules including chlorine or fluorine.

20. The method of claim 17, wherein the alkaline earth metal includes barium and the transition metal includes titanium, where ligand gas includes hexafluoro acetylacetonate (hfacac), 1,1,1,2,2,3,3,7,7,8,8,9,9,9-tetradecafluoro-4,6-nonanedione, acetylacetone, perfluoroethyl trifluoroacetoacetate, cyclopentadienide, benzene, tropylium cation, cyclooctatetraendiide, methylamine, dimethylamine, trimethylamine, ethylenediamine, ethylenediaminetetraacetic acid, hexamethylenediamine, N,N,N′,N″,N″-pentamethyldiethylenetriamine, porphine, diethyl ether, tetrahydrofuran, 12-crown-4, 15-crown-5, 19-crown-6, dibenzo-18-crown-6, 4,13-diaza-18-crown-6, [2.2.2]cryptand, or cucurbit[6]uril, and wherein the reactive gas includes molecules including chlorine or fluorine.
